(19) United States
(12) Patent Application Publication
(10) Pub. No.: US 2002/0116682 A1
(43) Pub. Date: Aug. 22, 2002

(54) Subtraction in a viterbi decoder

(75) Inventor: Cormac Brick, Killorglin (IE)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: PMC Sierra Limited, Dangan (IE)

(21) Appl. No.: 09/904,382

(22) Filed: Jul. 12, 2001

(30) Foreign Application Priority Data
Jul. 14, 2000 (IE) S2000/0574

(51) Int. Cl. H03M 13/03

(52) U.S. Cl. 714/795

(57) ABSTRACT

A Viterbi decoder for decoding a convolutional code. For each possible state, an accumulated error AE is maintained at 66. As each codeword Rx-GP is received, the errors between it and the code groups of all the transitions are determined at 65. For each possible new state, logic 68 determines the errors of the two transitions leading from old states to that new state, adds them to the accumulated errors of those two old states, and determines the smaller of the two sums. Path logic 67 records the corresponding transition, updating a record of the path leading to the new state. Tracing back along a path a predetermined and sufficiently large number of transitions, the input bit or bits corresponding to the transition so reached are taken as the next bit or bits in the stream of decoded bits. To renormalize the accumulated errors, the smallest accumulated error is determined by a minimum accumulated error determining unit 57 and subtracted from the errors from unit 65 by subtractors 80 before the additions and comparisons in logic 68. The unit 57 comprises a tree of comparators fed with the accumulated errors.

### FIELD OF THE INVENTION

The present invention relates to error-correcting codes, and more specifically to Viterbi decoders therefor.

### CROSS-REFERENCE TO RELATED PATENT APPLICATIONS

The present application is related to another application filed concurrently herewith entitled “Minimum Error Detection in a Viterbi Decoder” by the same inventor and subject to assignment to the same assignee, the contents of which are incorporated by reference in their entirety herein.

### BACKGROUND OF THE INVENTION

Error-correcting Codes

Error-correcting codes (ECCs) are well known. In the classical form of error-correcting code, a word of predetermined length is converted into a longer code word in such a way that the original word can be recovered from the code word even if an error has occurred in the code word, typically in storage and retrieval or in transmission. The error will be the change of a bit (or up to a specified number of bits) between 0 and 1. The coding involves an expansion of the word length from the original word to the coded word to introduce redundancy; it is this redundancy which allows error correction to be achieved. Many such error-correcting codes use Galois field operations. A Galois field is an algebraic system formed by a collection of finite number of elements with two dyadic (two-operand) operations that satisfy algebraic rules of closeness, association, commutation and distribution. The operations in this field are performed modulo-q, where q is a number of elements in the field. This number must be a prime or a power of prime. The simplest Galois field is a binary field GF(2).

This type of error-correcting code operates on discrete words and it is known as a block code. In addition to this type, a second type of error-correcting code has been developed, which operates on a continuous stream of bits. A well-known form of such error-correcting code is known as a convolutional code. In contrast to block codes where each code word depends only on the current input message block, the output of the convolutional code depends on the state of a finite-state encoder, as well as current inputs.

Convolutional codes can be characterised by the number of outputs, number of inputs, and code memory, often written as (k, n, m). The incoming bits are fed into the encoder in blocks of n bits at a time, and the code memory value m represents the number of previous n-input blocks that have influence on the generation of k parallel output bits that are converted to serial stream afterwards. For a (k, 1, m) convolutional code, the convolutional encoding can be regarded as involving the coding (without expansion) of a bit stream in k different ways and the interleaving of the resulting code streams for transmission. Thus for each bit in the original bit stream, there is a group of k bits in the coded bit stream. These codewords can be decoded to recover the original bit stream, and the redundancy allows the correction of errors (provided that the errors are not too dense). The coding normally uses Galois field operations. The structure of a convolutional code is easily represented with a trellis diagram (discussed below).

Viterbi Decoding

Various techniques for decoding such convolutional codes have been proposed. Of these, Viterbi decoding is particularly attractive, because it is theoretically optimal, i.e. achieves the maximum likelihood decoding. However, the extent to which Viterbi decoding can be used can be restricted by hardware constraints. The nature of convolutional coding and of Viterbi decoding is discussed in more detail below.

### SUMMARY OF THE INVENTION

Viterbi decoding involves maintaining a set of accumulated errors. On each decoding cycle, i.e. for each received code word, fresh error values are generated, and the accumulated errors are updated by adding in the fresh error values. To limit the extent to which the accumulated errors can grow, they are periodically renormalized by determining the smallest accumulated error and subtracting this from all the accumulated errors. The number of operations in this renormalization is determined by the number of states in the trellis diagram, 2^{m} (m is the coding memory value), which is usually greater than 32.

The present invention is concerned with the handling of the accumulated errors.

The invention is concerned with the renormalization of the accumulated errors once the smallest accumulated error has been determined. In a conventional Viterbi decoder, renormalizing involves subtracting the smallest accumulated error from each of the accumulated errors. In the present system, the smallest accumulated error is subtracted from the fresh transition error values before those values are added to the accumulated errors. As the number of transitions (branches) in the trellis diagram is usually much smaller then the number of states 2^{m}, significant saving in computation is achieved.

### DETAILED DESCRIPTION

Convolutional coding, Viterbi decoding, and an exemplary improved Viterbi decoder embodying the invention will now be described in detail with reference to the drawings and the glossary at the end of the description. In the drawings:

### BRIEF DESCRIPTION OF THE DRAWINGS

FIG. 1 is a block diagram of a data transmission system using convolutional decoding;

FIG. 2 is a general block diagram of a convolutional coder;

FIG. 3 is a block diagram of a simple convolutional coder;

FIGS. 4A to 4C are trellis diagrams illustrating the coding and decoding;

FIG. 5 is a functional block diagram of a section of a standard Viterbi decoder;

FIG. 5A is a trellis diagram corresponding to FIG. 5;

FIG. 6 is a block diagram of the Viterbi decoder corresponding to FIG. 5;

FIG. 6A is a block diagram of the path logic unit of FIG. 5;

FIG. 7 is a block diagram of the smallest accumulated error detector; and

FIG. 8 is a general block diagram of the present Viterbi decoder.

Coded Data Transmission Systems

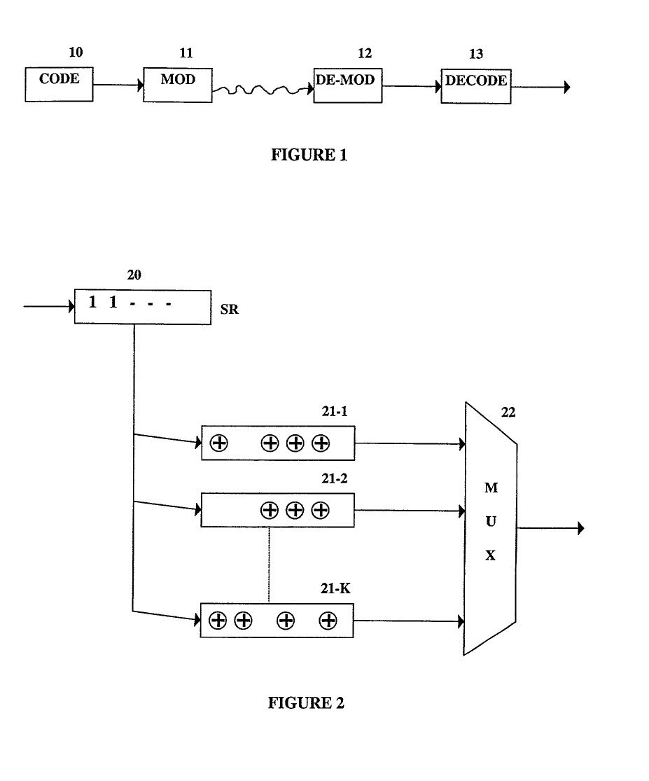

FIG. 1 shows the general nature of a typical data transmission system using convolutional coding. The input bit stream is fed to a coder 10 which drives a modulator 11. The signal from the modulator is transmitted to a demodulator 12 which feeds a decoder 13 which recovers the original bit stream. The modulator and demodulator may sometimes be omitted, but are often required if the signal is to be transmitted over a considerable distance. Various forms of modulation, such as frequency modulation (or frequency shift or phase shift keying), quadrature amplitude modulation, and/or pulse amplitude modulation, may be used.

Convolutional Codes and Coders

FIG. 2 shows the principles of a convolutional encoder. A shift register 20 is fed with the stream of input bits. There are k modulo-2 adders 21-1, 21-2, . . . , 21-k, each of which is fed with the contents of the shift register. The outputs of the adders are fed to a multiplexer 22 which scans across all adders each time a fresh bit is fed into the shift register, so that it produces a group of k output bits for each input bit. Each adder is fed from a different combination of the stages of the shift register. Each adder may be formed in any convenient way, e.g. as a line of 2-input modulo-2 adders or as a single multi-input modulo-2 adder.

If desired, the expansion ratio can be reduced by passing the input bits into the shift register in sets of n bits instead of singly, so that the total expansion ratio is k/n. This is equivalent to passing the input bits into the shift register singly but chopping the output stream from the multiplexer by passing only every nth codeword and deleting the intervening codewords (or similarly chopping the output streams from the various adders).

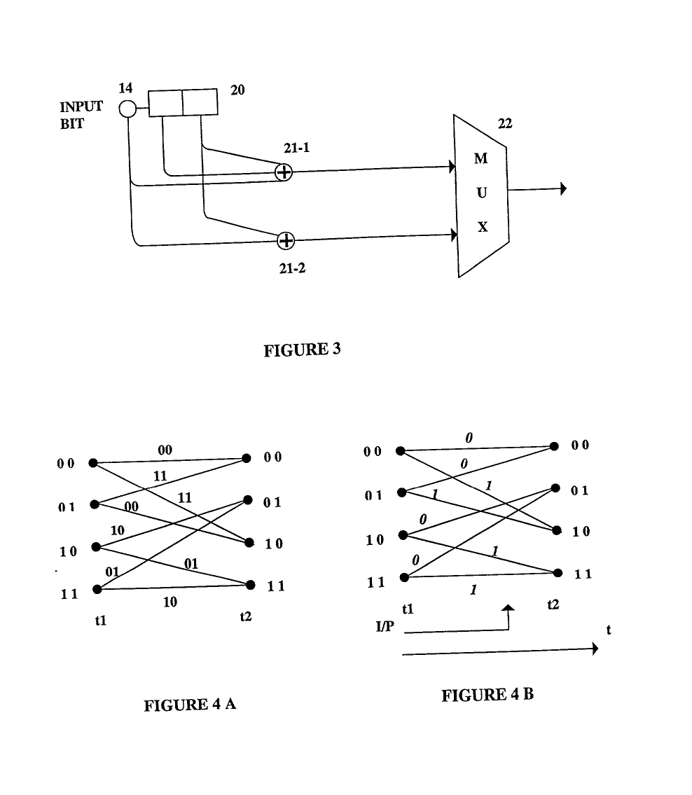

FIG. 3 shows a very simple specific example of the coder of FIG. 2, in which the shift register is 3 bits long, there are 2 adders 21-1 and 21-2, and there is no chopping compression. It is convenient to discuss convolutional code with reference to this simple specific example; the principles can readily be generalized where necessary. Adders 21-1 and 21-2 have the abstract patterns 111 and 101 respectively.

The operation of this coder can easily be seen, e.g. by the tabulation shown in Table I. The first column shows the sequence of bits in the input stream, the second column shows the contents of the shift register, and the last two columns show the outputs of the two adders 22-1 and 22-2 respectively. (We assume that the output codeword stream begins only when the input bit stream starts, so there are no output bits for the first row, which shows the initial or quiescent state.) Thus the input bit stream 1101100 . . . produces the output stream 11 01 01 00 01 01 11 . . . (where the grouping of the output bits has been emphasized).

TABLE I

| Input Bit | Register | State at | State at | Output Codeword | |
|---|---|---|---|---|---|
| at Time t | Contents | Time t | Time t + τ | Bit 1 | Bit 2 |
| | 00 | 00 | | | |
| 1 | 00 | 00 | 10 | 1 | 1 |
| 1 | 10 | 10 | 11 | 0 | 1 |
| 0 | 11 | 11 | 01 | 0 | 1 |
| 1 | 01 | 01 | 10 | 0 | 0 |
| 1 | 10 | 10 | 11 | 0 | 1 |
| 0 | 11 | 11 | 01 | 0 | 1 |
| 0 | 01 | 01 | 00 | 1 | 1 |
| — | — | — | — | — | — |
| — | — | — | — | — | — |

The output codeword is determined by the contents of the shift register and the arrangement of modulo-2-adders, so there are 2^{k} possible output codewords. However, the fact that the input bit combinations are generated by feeding the input bits to a shift register strictly limits the transitions between the input bit combinations; each input bit combination can be followed by only 2 possible combinations (and each output codeword combination can be preceded by only 2 possible input bit combinations). The last (right-most) bit in the shift register disappears as the next input bit appears and the coder changes from its current state to its next state. We can therefore regard the contents of the m stages of the shift register as the state of the coder. These states are shown in the middle column of Table I.

Trellis Diagrams

We can also draw up a state transition diagram accordingly. This can be done abstractly, but it is valuable to use separate columns for the current and next state, so that the time sequence between two states corresponds to a conventional time axis.

FIG. 4 shows the resulting state transition diagram. The states are 00, 01, 10, and 11 as listed at the sides of FIG. 4A, and the states at the two successive times are shown in the two columns t1 and t2. The possible state transitions are shown as lines joining the state points in the two columns, so forming a pattern which is termed a trellis pattern.

The output codeword (bit pair) for each possible state transition is shown as a digit pair labelling the trellis line, in FIG. 4A; FIG. 4B shows the same trellis diagram but with each trellis line labelled with the input bit causing that transition. The state transition itself is given by taking the initial state, dropping its right-hand bit, and adding the input bit to its left-hand end.

It is interesting to note that the trellis diagram actually consists of a number of separate 4-line portions, which are termed butterflies.

This state transition diagram can be repeated indefinitely for successive input bits, as shown in FIG. 4C. The input bit sequence can be traced out along the trellis lines, bit by bit, and the output codeword sequence can be read off the resulting path (which will normally be a zig-zag along the trellis).

Decoding and Decoders

With block codes (i.e. error-correcting codes for words of fixed length of 1 bits, or block encoders), the decoding can be regarded in principle as consisting of listing the codes for all the 2^{l} possible words and comparing the actual coded word with all the entries in the list to determine the degree of match with each entry in the list. The word giving the entry with the closest match is taken as the desired word. (In practice, the code is normally designed so that decoding can be performed algebraically by suitable logic rather than by generating the full list and direct matching.)

This requires some way of defining and measuring the degree of match; that is, some measure or metric must be defined. The usual metric is the Hamming distance, which is the number of bits which are different in the coded word as received and the chosen entry in the list. The Hamming distance of the coded word as received from the correct version of the coded word is simply the number of bits which have become erroneous as the result of the transmission; for reasonably low error rates, this number will be smaller than the Hamming distance to any other correctly coded word.

For decoding convolutional codes, the same principle applies of selecting as the output that bit stream which has the best match with the actual received codeword stream. However, since the bit and codeword streams are continuous and of potentially infinite length, some sort of limit must be imposed on the length or interval in the streams over which matching is carried out.

As a preliminary point, synchronization may be needed to group the bits of the codeword stream correctly. Since the received codeword stream is generally continuous, the correct way of dividing it up into codewords of length k must be determined. If modulation is used as well as coding, however, the modulation may automatically ensure correct synchronization, as for example if each transmitted codeword is modulated as a single pulse amplitude.

If incorrect synchronization is possible, this can be detected relatively easily, because a received codeword stream which is not correctly synchronized will generally be pseudo-random as far as the decoding is concerned and its error rate will be the maximum possible. So it can be assumed that correct synchronization has been achieved before decoding is started.

The Hamming distance, and most other metrics used for decoding block codes, treat the individual bits of the code word separately; there is no interaction between different bits. For a convolutional code, the code units or elements must obviously be the codewords of the received codeword stream, not the individual bits of that stream. Given that, however, the distance measure is normally chosen so that it can be computed by taking the codewords pairwise and summing the individual codeword distances. (It is possible to choose a metric which involves multiplying the individual distances, but by taking logarithms, that can be converted to an additive form.)

The required comparison can thus be regarded in principle as taking some suitable length of the received codeword stream and comparing it with all possible valid group streams of that length. (A valid codeword stream is a stream which can be generated by an input bit stream without any errors.) A group-wise metric must therefore be used. However, a bit-wise metric must similarly be used within the group comparisons, so the overall metric is bit-wise. For a pure binary received codeword data stream, the natural metric is the Hamming distance. However, with some forms of modulation, another metric such as a Euclidean distance metric may be more appropriate.

Modulation

As noted above, convolutional coding often uses modulation as well as coding, and the modulation often uses an amplitude component. When the communications channel is not band-limited, the encoding and modulation functions are usually done separately, and the code is optimised according to the Hamming distance. The redundancy required for coding is obtained by increasing the signal bandwidth (using faster information rates). However, on band-limited channels, the only way to achieve redundancy for coding is to increase the number of signal constellation points, because faster signalling is not possible due to bandwidth constraints. Thus, the encoding and modulation functions are performed jointly so as to maximise the Euclidean distance between the allowed symbol sequences. Hence, the encoding is done in the modulation symbol space and not on raw bits. The technique is known as trellis coded modulation (TCM) and the method of mapping the coded bits into signal points is called mapping-by-set partitioning.

As noted above, the principle of decoding a convolutional code is the same as for decoding a finite word length code; the actual received codeword stream is compared with all possible correctly coded codeword streams and the input bit stream giving the best match is selected. With convolutional codes, however, it is generally not possible to achieve this by algebraic or logic techniques similar to those used with finite word length codes. The matching involves an actual comparison with possible corrected code codeword streams, or something closely approaching that.

Each possible codeword stream can be traced out along the trellis diagram of the coder. We can write out the received sequence of codewords above the trellis diagram; and we can label each line of the trellis with the distance or error of the received codeword from the codeword of that trellis line. If we trace out some possible input bit stream along the trellis diagram, the total distance or error of that stream as a whole from the received codeword stream can be determined by adding the individual distances of each trellis line in turn along the track we are tracing out (this is because we are using a group-wise metric).

Viterbi Decoding Principles

The general principles of Viterbi decoding can be summarised roughly as follows.

First, convolutional coding must be understood. A convolutional coder is a coder which expands an input bit stream by passing it to a shift register feeding a plurality of distinct modulo-2 adders whose outputs are interleaved to produce a stream of output codewords. There is a plurality of possible states for the coder. For each new state there are 2ⁿ possible transitions from an old state and for each old state there are the same number of possible transitions to a new state. Each possible input bit stream thus traces out a respective path through a sequence of state transitions.

A Viterbi decoder is a decoder for such a code. For each possible state, an accumulated error is maintained. As each codeword is received, the match errors, i.e. the errors between it and the codewords associated with all of the transitions are determined. For each possible new state, the match errors of the two transitions leading from old states to that new state are added to the accumulated errors of those two old states. The smaller of the two sums is determined, and the corresponding transition recorded, to update a record of the path leading to the new state. Tracing back along a path a predetermined and sufficiently large number of transitions, the input bit or bits corresponding to the transition so reached are taken as the next bit or bits in the stream of decoded bits.

Viterbi Decoding

The Viterbi algorithm consists essentially of the procedure described above, but taking into account a critical point; that when paths merge, the path with the larger overall accumulated error value can be discarded.

Considering the matter in more detail, the number of states in the trellis diagram is 2^{m*n}. For the case where n=1, the number of paths being traced will initially double with each step into the trellis diagram; but when the path tracing has reached into the diagram to sufficient depth, the paths will start to join in pairs. Looking backwards into the trellis diagram, two paths merge at each of the 2^{m} states. These two paths will normally have different accumulated error sums. We can therefore discard the path with the larger error, and retain only the path with the smaller error. (If the two paths have the same error, we cannot discriminate between them, and we can pick either of them at random.) This process is called survivor selection, as one of the two possible paths into each state is selected as the survivor and the other is discarded.

We therefore have to retain a record of 2^{m} paths, but no more. At each time step, for each of these paths there are two potential routes forward to the next time point. But at that point, those potential routes converge in pairs, and from each pair, we discard the one which has the larger accumulated error value. A record of the paths which are selected as survivors are stored in a path survivor memory, which essentially stores a representation of the trellis diagram (ie the diagram for the actual stream of codewords).

Tracing the paths back through the trellis diagram, they will merge in pairs, until eventually a single path is reached. Following forward from that point, that single path branches repeatedly until the current time point is reached, with all surviving branches reaching that point. There are no branches left which stop before that point; when a branch is discarded, it is pruned all the way back until a point on a surviving branch is reached.

Viterbi decoding consists essentially of carrying out the process just described, and taking output bits from the tree of branches at the point where all the branches have merged into a single branch.

The exact sequence in which the branches split at successive time points depends on the exact nature of the input codeword sequence, and there is no limit on how far back one may have to go until all branches merge into a single path. The length of the path survivor memory is chosen such that the chance of there being more than one branch going back beyond that number is sufficiently low. Since all paths will normally have coincided by that point, the first (oldest) entry in any path in the memory can be taken. The length of the path survivor memory is called the traceback depth, D, which determines the overall latency of the Viterbi decoder, and also has an impact on the decoder performance. Generally, the longer the traceback depth, the more accurate the Viterbi decoding is.

It is possible that the paths may not in fact have converged by that point. Picking a path at random may therefore result in an error. The chance of error can be reduced by choosing the path with the smallest accumulated error; as that path is the most likely to be correct. (Even if all the paths have coincided by the end of the path survivor memories, it is possible, though unlikely, that there may be an error.) For most convolutional codes, errors do not propagate, in the sense that if the wrong path is chosen in this way, that path will eventually merge with the correct path.

Since the input bit stream is indefinitely long, errors will of course accumulate indefinitely, so the accumulated errors will be unbounded. For Viterbi decoding however, it is only the differences between accumulated errors which is important. Thus, to reduce the size of the accumulated errors and prevent overflows, all the accumulated errors for the different paths can be compared at suitable intervals (typically on each time step) to determine the smallest, and this smallest value can be subtracted from each of the accumulated errors. This introduces a finite bound on the accumulated errors which is equal to m times the largest error which may be associated with the transition between any two states.

Viterbi Decoder

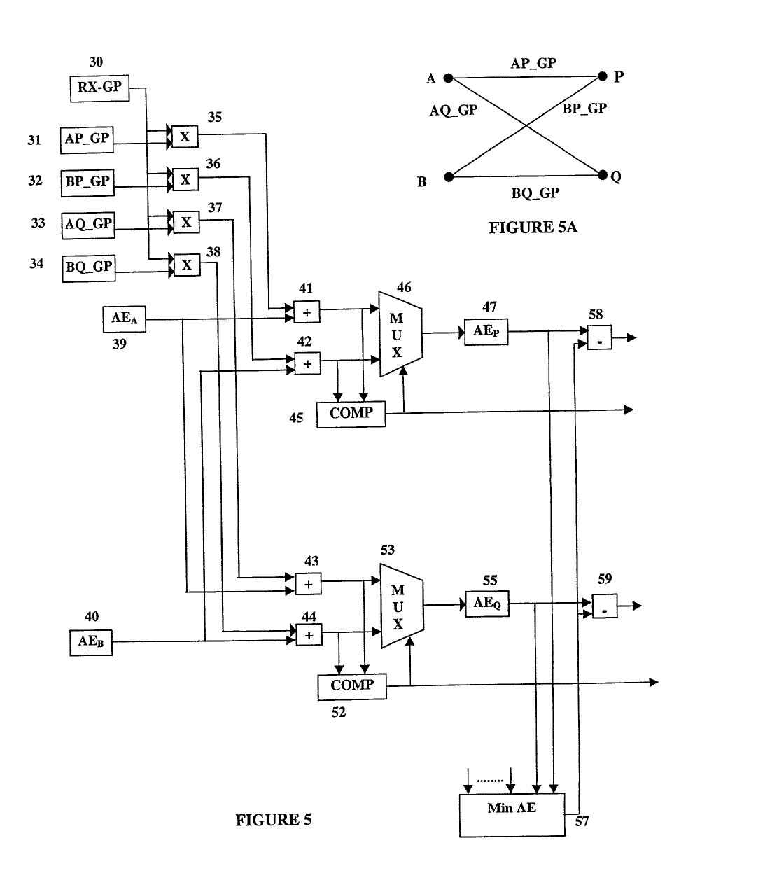

FIG. 5 is a diagram showing the logical functions performed by the Viterbi decoder for one butterfly of the trellis diagram. FIG. 5A shows the butterfly; we assume that the input states are A and B and the output states are P and Q. For the two input states, the accumulated errors are AE_{A} and AE_{B}.

For each of the four trellis lines, a match error value has to be calculated which indicates the degree of match between the received codeword and the codeword represented by that trellis line. (More precisely, the error value indicates the degree of mismatch—a perfect match gives an error value of 0.) The trellis lines are labelled with their corresponding output codewords, their corresponding match error values (not shown) are given by OBE_{A,P}, OBE_{A,Q}, OBE_{B,P}, and OBE_{B,Q}. For state P, the two potential accumulated error values AE_{A}+OBE_{A,P} and AE_{B}+OBE_{B,P} have to be calculated and compared, and the smaller value is selected as the accumulated error for state P. State Q is treated similarly.

FIG. 5 is a functional block diagram for this. The received codeword RX-GP is held in a register 30, and the four codewords AP-GP, BP-GP, AQ-GP, and BQ-GP for the four trellis lines are held in registers 31-34 (these codewords are the trellis line labels of FIG. 4A, i.e. the output signals generated by the encoder for a given state transition). These registers feed a set of computational units 35-38 as shown, which generate the match error values OBE_{A,P}, OBE_{A,Q}, OBE_{B,P}, and OBE_{B,Q} just discussed.

There are two input path error registers 39 and 40 for the path errors AE_{A} and AE_{B}. These feed four adders 41-44 which are also fed with the four match error values OBE_{A,P} to OBE_{B,Q} as shown, to generate potential accumulated errors. Adders 41 and 42 feed a comparator 45 which determines which is the smaller, and controls a multiplexer 46 which passes that value to a register 47 for the accumulated error AE_{P} for state P. There is a similar comparator 52, multiplexers 53 and 54, and accumulated error register 55 for the output state Q, arranged and connected as shown.

The outputs of the output state accumulated error registers AE_{P} 47 and AE_{Q} 55, together with the corresponding outputs from the rest of the decoder (i.e. all the other butterfly sections), are fed to a minimum accumulated error detector 57, which determines the smallest of the accumulated errors for all the output states. This unit 57 consists essentially of a tree of comparators, with the top level comparing the signals direct from the output states in pairs, the next level comparing the outputs of top level in pairs, and so on.

The accumulated errors for the output states P and Q are fed from the pair of registers 47 and 55 to a pair of subtractors 58 and 59, where the output of the detector 57, which is the smallest of all the accumulated errors, is subtracted from them.

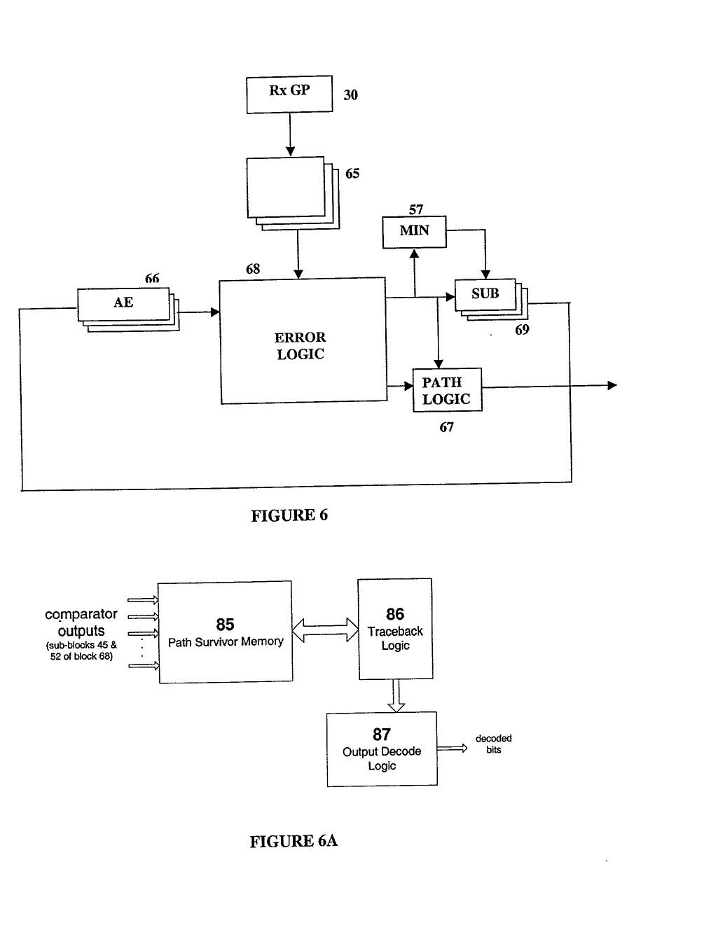

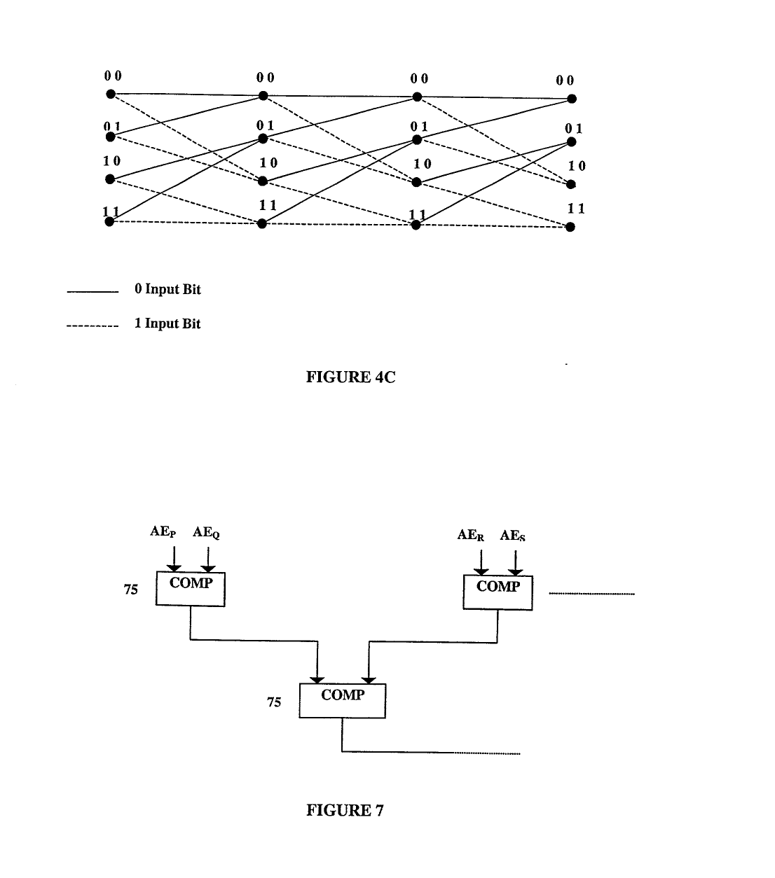

FIG. 6 is a block diagram of a complete Viterbi decoder. It will of course be realized that this is a conceptual or functional diagram, which may be implemented in various ways.

Register 30 is the received codeword register 30 of FIG. 5. This is shown as feeding a set of blocks 65, one for each butterfly, each of which corresponds to the registers 31-34 and computational units 35-38. However, these blocks are not wholly distinct. In practice the number of modulo-2-adders (k) (21-1 to 21-k in FIG. 2) is smaller than the shift register length (m) hence there are more states and trellis lines between the states than there are allowable codewords. Consequently a given codeword is associated with more than one trellis line. For each of the possible codeword, operations are performed in block 68 to calculate the error between an allowable codeword and the received codeword. Such errors are then assigned to the same trellis lines as the allowable codeword is associated with.

There is a set of accumulated error registers 66, one for each input state, which feed a logic unit 68, which is also fed with the outputs of the blocks 65. Block 68 produces a set of outputs forming the accumulated errors for the new states. These accumulated errors are passed to a set of subtractors 69, each of which corresponds to the two subtractors 58 and 59 of FIG. 5. They are also fed to a minimum accumulated error detector 57, which is the detector 57 of FIG. 5, and which feeds the subtractors 69.

These decremented accumulated errors are fed back to the accumulated error registers 68. The accumulated error registers 68 are thus updated with new values for each received codeword. (In FIG. 5, the input state registers 39 and 40 and output state registers 47 and 55 are shown as separate for explanatory purposes. Also, as indicated above, the layout shown in FIG. 6 is also explanatory, and the precise arrangement of the various components such as the various registers, and indeed the components, can be varied widely provided that the required functional result is achieved.)

A path logic unit 67, shown in more detail in FIG. 6A, maintains a record of the various paths as they are being traced through the trellis diagram and generates the decoded output bit stream. This unit comprises the path survivor memory 85 and an associated traceback logic unit 86 and output decode logic unit 87.

The path survivor memory is essentially a shift register memory. Its depth is the traceback depth, D, which is the desired branch length over which tracking is desired, i.e. the length chosen to give an acceptable probability that all branches will have merged by then, as discussed above. The width of the shift register is the width of the trellis diagram, i.e. the number of states of the trellis diagram. The outputs of the two comparators 45 and 52 of the butterfly of FIG. 5 are fed into the path survivor memory, and the other butterflies of block 68 do likewise.

The path survivor memory will therefore contain a map of the trellis diagram, with a bit for each point indicating which branch from that point was taken. In general, the paths or branches through the trellis diagram will wander irregularly through the diagram, intertwining and merging. Although the contents of the path survivor memory represent the paths, tracing a path requires tracking it through the path survivor memory stage by stage.

The path route (traceback) logic circuitry 86 performs a traceback procedure through the path logic memory. This procedure essentially begins at the state with the smallest accumulated error, and uses the contents of the path survivor memory to determine the preceding state on the path which ends at this state in the trellis diagram. This procedure is repeated until the state at the start of the trellis diagram is recovered. The output decode logic 87 is then able to determine the corresponding output bit, and outputs the value of that output bit as the next bit of the decoded bit stream reproducing the original input bit stream.

Once the decoded bit has been found, the oldest path survivor data is discarded, the contents of the path survivor memory are conceptually shifted one place, and the new path survivor data is written into the newly vacant memory position at the end of the memory. In practice this may be realised by means of a shift register, or by using incremental address pointers to memory data which does not move.

However, obviously any convenient method of path trace-back can be used.

Detailed Description of the Present Invention

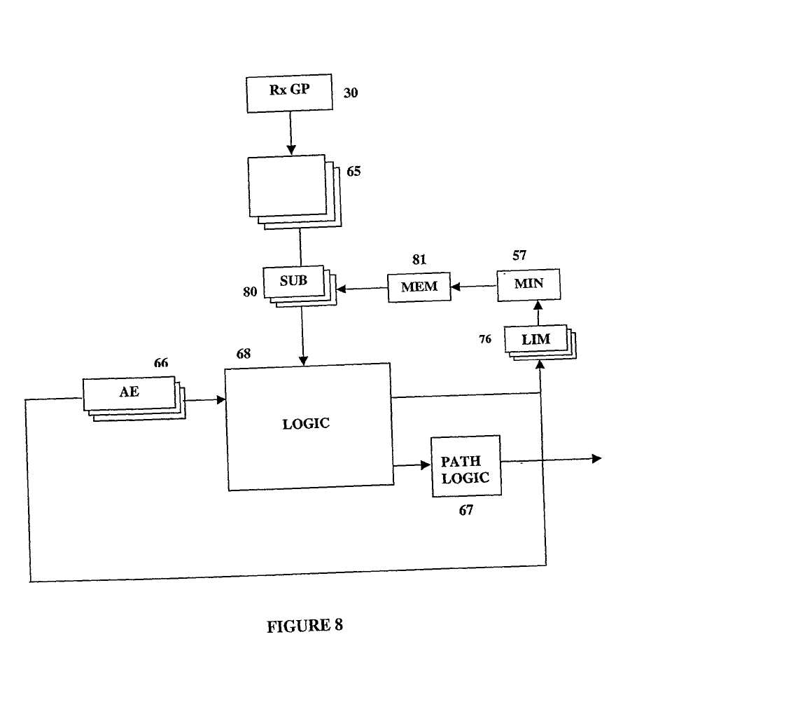

With this background, the salient features of the present decoder can now be described with reference to FIG. 8, which shows the present decoder.

Improved Subtractor Organisation

Consider the subtractors 69. There is one subtractor for each state. If the number of stages in the shift register of the convolutional coder is m, the number of states will be 2^{m}, and the number of subtractors will be the same.

Returning to FIGS. 5 and 5A, suppose that the accumulated error for output state P is derived from input state A. Then the accumulated error AE_{P} is AE_{A}+OBE_{A,P}, and the output from subtractor 58 is AE_{P}−MINAE (where MINAE is the output of the detector 57), i.e. (AE_{A}+OBE_{A,P})−MINAE. We have realised that this can be rearranged as AE_{A}+(OBE_{A,P}−MINAE), and implemented by performing the subtractions at the outputs of block 65 instead of block 68. As shown in FIG. 8, the present decoder is similar to FIG. 6, but the subtractors 69 are omitted, and a block of subtractors 80 is included between blocks 65 and 68.

In the FIG. 6 system, the subtractions are performed after the minimum accumulated error has been found. In the FIG. 8 system as described so far, they are apparently performed before the minimum accumulated error has been found, which involves a logical difficulty. To overcome this, a minimum accumulated error memory 81 is included as shown. The effect of this is that the minimum accumulated error determined for one received codeword is subtracted from the errors from block 65 when the following received codeword is being processed, i.e. after the minimum accumulated error has been found. This may result in the actual smallest accumulated error being slightly larger than 0, but this will have no significant adverse effect.

The number of subtractors required in block 80 is the number of possible output codewords which the convolutional encoder can produce. If the coder has k modulo-2 adders, then the number of bits in the codewords will be k and the number of possible output codewords will be 2^{k}. Thus the present decoder requires 2^{k} subtractors, compared to the 2^{m} subtractors required by the conventional FIG. 6 type decoder. In other words, the number of subtractors required is determined by the shift register length for a conventional decoder, but by the number of modulo-2 adders (which equals the code word length) for the present decoder. As stated earlier, in practice, the number of modulo-2 adders will normally be considerably smaller than the shift register length, so the present decoder will normally result in a considerable reduction in the number of subtractors.

Parallelism of the Architecture

Up to this point, all references to the survivor selection architecture of the Viterbi decoder have made reference to a fully parallel architecture, i.e. one in which there is sufficient logic to perform the survivor selection for each of the 2^{m-1} butterflies in one single operational step. In other words, all of the processing is done within each single symbol period, τ.

To some extent, the processing can be done every s-th symbol period, or, more importantly, each set of processing operations can be spread over s symbol periods. This allows a more serial architecture to be used, which requires 1/s times the logic required for a fully parallel architecture. In some cases some obvious additional logic may be required, beyond that described herein, to achieve this, as is always the case with such parallel to serial architecture mappings.

The degree of parallelism employed is an important design trade-off has significant impact on the appearance of the architecture.

List of symbols used
A: Symbols Used in Text

| | |
|---|---|
| A, B | Input states |
| AEₛₜₐₜₑ₍ᵢ₎ | Accumulated Error of a given state i |
| AP-GP | Bit group for the State A to State P trellis line |
| AQ-GP | Bit group for the State A to State Q trellis line |
| BP-GP | Bit group for the State B to State P trellis line |
| BQ-GP | Bit group for the State B to State Q trellis line |
| D | Window length |
| k | Number of codeword bits (= number of |
| | Modulo-2 adders) |
| l | Number of bits in a hypothetical word |
| m | Memory length of the encoder shift register |
| MINAE | Minimum Accumulated Error |
| MEUB | Minimum Error Upper Bound |
| n | Number of input data bits per codeword |
| OBEₛₜₐₜₑ₍ᵢ₎ₛₜₐₜₑ₍ⱼ₎ | Match error on transition from State i to State j. |
| | (More precisely, this is a transition mismatch metric, |
| | defined as the mismatch between the symbol generated in |
| | the encoder by a particular encoder transition and the |
| | symbol received at the decoder input) |
| P,Q | Output states |
| RX-GP | Received Bit Group |
| s | Logic reduction factor if a partially serial |
| | architecture is used |
| t | Time variable |
| τ | Symbol Period (the time between input bits to the |
| | encoder, and the time between successive codewords) |
| t1, t2 | Times used in analysis of state transitions |

B: Symbols Used in Graphics

| | |
|---|---|
| ACC ERR | Accumulated Error |
| COMP | Comparator |
| DE-MOD | Demodulator |
| IP | Input |
| LIM | Limiters |
| MEM | Memory |
| MOD | Modulator |
| MUX | Multiplexer |
| SR | Shift Register |
| SUB | Subtractor |

C: Mathematical Expressions

| | |
|---|---|
| 2^{m}*ⁿ | Number of states |
| 2ⁿ | Number of trellis transitions into/out of each state |
| k/n | Code ratio (expansion ratio) |
| m + 1 | Constraint length of code |

1. A Viterbi decoder for decoding a convolutional code comprising a sequence of codewords, comprising:
path memory means for recording paths forming sequences of states of the code;
means for maintaining, for each current state, an accumulated error;
error determining means for determining, as each codeword is received, the errors between it and all possible state transitions of the code;
logic means comprising, for each possible new state, adding means for adding the errors of the transitions leading from old states to that new state to the accumulated errors of those old states, means for determining the smaller of the sums generated by the adding means, and means for recording the corresponding transition in the path memory means;
normalizing means comprising a comparator tree for determining the smallest accumulated error and subtractor means for decrementing all accumulated errors by the output of the comparator tree; and
output means for tracing back a predetermined number of transitions along a path and outputting the bit or bits corresponding to the transition so reached as the next bit or bits in the stream of decoded bits;
and wherein the subtractor means are located between the error determining means and the adder means.

2. A method of Viterbi decoding for decoding a convolutional code comprising a sequence of codewords, comprising:
recording, in path memory means, paths forming sequences of states of the code;
maintaining, for each current state, an accumulated error;
as each codeword is received, determining, by error determining means, the errors between it and all possible state transitions of the code;
for each possible new state, adding the errors of the transitions leading from old states to that new state to the accumulated errors of those old states, determining the smaller of the sums generated by the adding means, and recording the corresponding transition in the path memory means;
determining the smallest accumulated error by means of a comparator tree and decrementing all accumulated errors by the output of the comparator tree; and tracing back a predetermined number of transitions along a path and outputting the bit or bits corresponding to the transition so reached as the next bit or bits in the stream of decoded bits;
and wherein the decrementing is performed on the output of the error determining means.
